(19) United States
(12) Patent Application Publication
(10) Pub. No.: US 2006/0139887 A1
(43) Pub. Date: Jun. 29, 2006

(54) Electronic apparatus and television receiver

(75) Inventor: Tsuneo Kameda, Hanyu-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: KABUSHIKI KAISHA TOSHIBA

(21) Appl. No.: 11/318,628

(22) Filed: Dec. 28, 2005

(30) Foreign Application Priority Data
Dec. 28, 2004 (JP) P2004-381787

(51) Int. Cl. H05K 7/20

(52) U.S. Cl. 361/704

(57) ABSTRACT

An electronic apparatus including: a circuit board on which a heat-generating member is mounted; a shield case; and a heat-radiating member attached to the shield case for radiating heat released from the heat-generating member, wherein the heat-radiating member comprises side faces formed with bellows-like gathers.

### CROSS-REFERENCE TO RELATED APPLICATION

This application is based upon and claims the benefit of priority from the prior Japanese Patent Application No. 2004-381787, filed on Dec. 28, 2004; the entire contents of which are incorporated herein by reference.

### BACKGROUND

1. Field

The present invention relates to an electronic apparatus and a television receiver to which the electronic apparatus is applied. More particularly, the present invention relates to an electronic apparatus including a member for radiating heat released from an electronic component mounted on a circuit board, as well as to a television receiver to which the electronic apparatus is applied.

2. Description of the Related Art

A related-art electronic apparatus, such as a television receiver, is usually configured such that a plurality of circuit boards, on which a tuner, a variety of signal-processing circuits, and the like are mounted, are disposed inside a package which constitutes the apparatus.

In general, some of these circuit boards constitute an electronic apparatus which is housed in a shielding case made from, e.g., a metal so as to shield electromagnetic waves generated from the thus-mounted electronic circuit. In addition, some of the circuit boards have the configuration in which a heat-generating component, such as an integrated circuit (hereinbelow abbreviated to an “IC”) for performing various types of signal processing, is included as an electronic component mounted on a mounting face.

Accordingly, in some electronic apparatuses of the configuration in which circuit boards are housed in a metal shielding case, heat released from heat-generating components, such as an IC on the circuit boards, is built up inside the shielding case, thereby causing an increase of the temperature inside the shielding case and/or the electronic component per se. As a result, in some cases, there arise problems, such as instable operation of electronic circuits mounted on the circuit boards and degradation in performance of the same.

To this end, a variety of means for radiating heat from heat-generating components on circuit boards disposed in a shielding case have conventionally been proposed, and put into practice.

For instance, an electronic apparatus disclosed in JP-A-9-293980 is configured such that a polygonal hole for fixing a radiator-fin-holding spring is formed in a side wall of a shielding case. The radiator-fin-holding spring fixed by means of the polygonal hole supports radiator fins, thereby bringing the radiator fins into press-contact with an electronic component on a circuit board housed in the shielding case.

According to means disclosed in JP-UM-A-2-104698, a heat-radiating member, and a heat-generating component mounted on a side face of the heat-radiating material in an electrically-insulated manner are pinched by a clip member which is formed from a plate spring and which has elasticity, thereby allowing conduction, to the heat-radiating member, of heat released from the heat-generating component.

An electronic apparatus disclosed in JP-A-9-64582 is configured such that a metal contact piece for heat radiation made from a metal is independently attached onto a portion of a flat face of a shielding case which is parallel with a circuit board. In this case, a projecting-flat-face section parallel with the flat face of the shielding case is formed on the metal contact piece for heat radiation; and the circumference of the raised-flat-face section is grooved to thus form a flexibly-deformable section. The means aims at, by means of employing the configuration, bringing the metal contact piece for heat radiation into contact with the heat-generating member without fail, thereby conducting, to the shielding case, heat released from the heat-generating member.

### BRIEF SUMMARY

The means disclosed in JP-A-9-293980 employs the radiator fins as means for radiating heat. However, the radiator fins involve a problem of increasing a space to be occupied. In addition, when such a configuration in which a heat-generating component and heat-radiator fins per se are disposed in a shielding case is employed, heat released from the radiator fins is considered to be built-up in the shielding case. Accordingly, there arises a problem that suppressing the temperature inside the shielding case low encounters difficulty.

In addition, according to the means disclosed in JP-UM-2-104698, a guide member for guiding the clip member must be formed on the circuit board. Consequently, the means involves a problem of an increase in man-hours and manufacturing cost in manufacture of components.

According to the means disclosed in JP-A-9-64582, one flat face of the heat-radiating-contact piece made from a metal is directly brought into contact with a face of the heat-generating component. At this time, since there is employed such a configuration that an elastic force of the heat-radiating-contact piece presses the heat-generating component, the heat-generating component is prone to being damaged.

The present invention provides an electronic apparatus, which includes a circuit board on which a heat-generating member is to be mounted, and a shielding case for housing the circuit board, the electronic apparatus being configured so as to be capable of radiating heat released from the heat-generating member mounted on the circuit board in the shielding case efficiently and without fail; as well as a television receiver to which the electronic apparatus is applied.

### BRIEF DESCRIPTION OF THE DRAWINGS

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is an external perspective view showing a schematic configuration of a television receiver to which an electronic apparatus of an embodiment of the invention is applied;

FIG. 2 is an exploded configuration diagram showing an exploded view of the electronic apparatus illustrated in FIG. 1;

FIG. 3 is an exploded configuration diagram of an essential portion showing in enlarged dimensions only an essential portion of the electronic apparatus illustrated in FIG. 2; and

FIG. 4 is an enlarged cross-sectional view of an essential portion showing a cross section of a principal portion in a state in which the electronic apparatus illustrated in FIG. 2 is assembled.

### DETAILED DESCRIPTION

Hereinbelow, the present invention will be described with reference to an embodiment illustrated in the drawings.

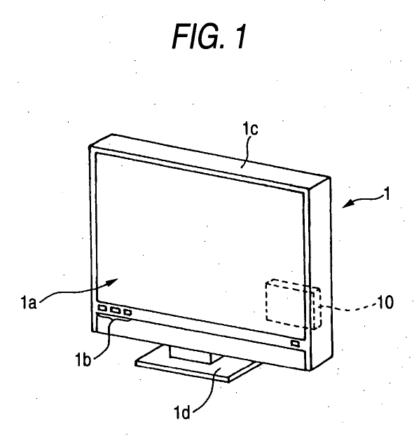

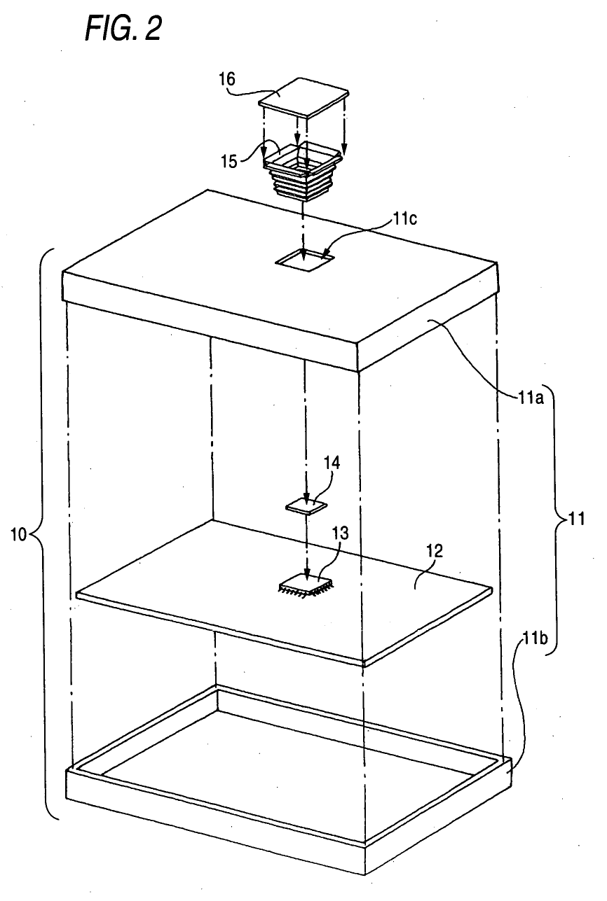

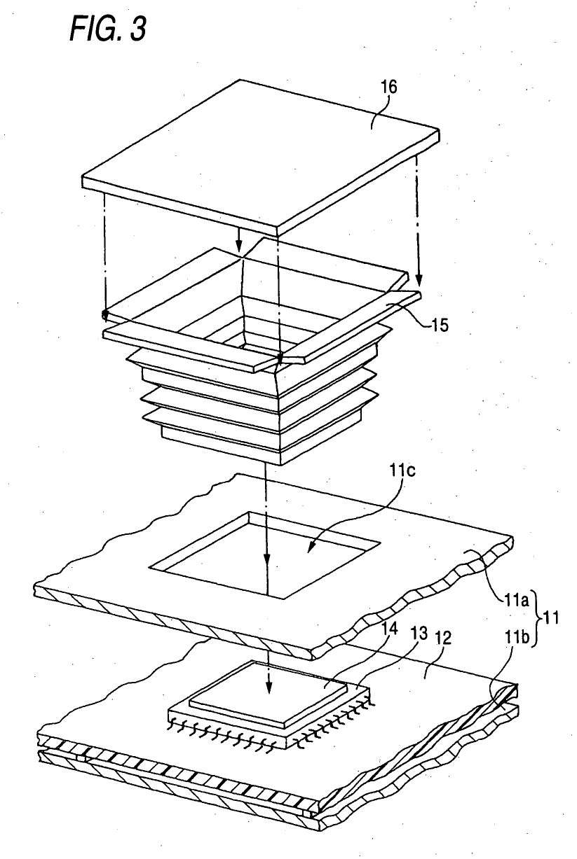

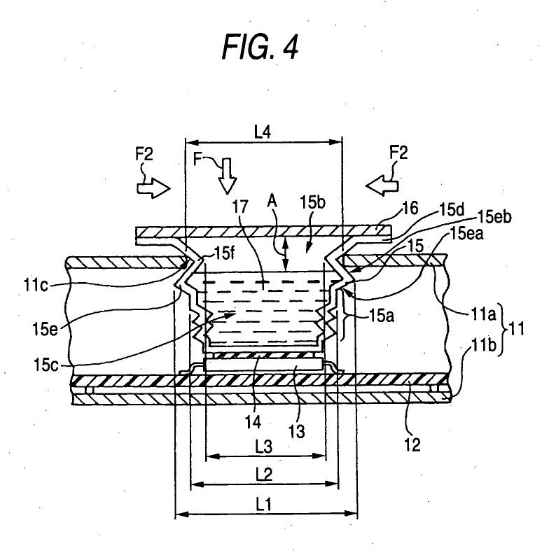

FIG. 1 is an external perspective view showing a schematic configuration of a television receiver to which an electronic apparatus of an embodiment of the invention is applied. FIG. 2 is an exploded configuration diagram showing an exploded view of the electronic apparatus of the embodiment. FIG. 3 is an exploded configuration diagram of an essential portion showing in enlarged dimensions only an essential portion of the electronic apparatus illustrated in FIG. 2. FIG. 4 is an enlarged cross-sectional view of an essential portion showing a cross section of a principal portion in a state in which the electronic apparatus illustrated in FIG. 2 is assembled.

First, the schematic configuration of the television receiver to which the electronic apparatus of the embodiment is applied will be described with reference to FIG. 1.

As illustrated in FIG. 1, a television receiver 1 to which an electronic apparatus 10 of the embodiment is applied primarily includes an external housing 1c of a box-like geometry; an image-display section 1a which is disposed so that a display screen thereof is exposed on a front face of the external housing 1c; an operation section 1b which forms a periphery of the image-display section 1a and which is disposed on a predetermined portion on the front face of the external housing 1c; a support base 1d for supporting the external housing 1c; and the like. The electronic apparatus 10 is disposed at a predetermined portion inside the external housing 1c.

Meanwhile, as the image-display section 1a, e.g., a CRT (cathode ray tube)-type display device, an LCD (liquid crystal display) device, a plasma display device, an electro luminescent (EL) display device, or the like, is adopted.

The configuration of the electronic apparatus 10 will be described with reference to FIGS. 2 to 4 hereinbelow.

As illustrated in FIG. 2, the electronic apparatus 10 of the embodiment includes a circuit board 12; a shielding case 11; a heat-radiating member 15; a thermal-conduction sheet 14; and the like. A plurality of electronic components including a heat-generating member 13, such as an IC, are mounted on the circuit board 12. The shielding case is formed into a box-like geometry by means of integrating a box section 11b disposed so as to cover a bottom face of the circuit board 12, and a 11d section 11a disposed so as to cover a top face of the circuit board 12. The heat-radiating member 15, which is formed independently of the shielding case 11, is attached in a hole 11c formed in a predetermined portion of the 11d section 11a of the shielding case 11. The thermal-conduction sheet 14, which is a thermal-conduction member, is disposed on the upper face of the heat-generating member 13.

The circuit board 12, on whose mounting face a plurality of electronic components are mounted, constitutes a tuner, an image-processing circuit, or the like. As described above, the plurality of electronic components to be mounted on the circuit board 12 include the heat-generating member 13, such as an IC. Meanwhile, in FIGS. 2 to 4, illustration of electronic components other than the heat-generating member 13 is omitted, for the sake of simplicity.

As described above, the shielding case 11 is formed into the box geometry by means of combining and integrating the 11d section 11a and the box section 11b. Each of the 11d section 11a and the box section 11b is formed by means of folding, e.g., a thin plate member (of a metal, and the like) having a magnetic-shielding function as well as exhibiting excellent thermal conductivity.

The 11d section 11a has such a configuration as to be detachable with respect to the box section 11b. No specific illustration is provided for a built-up structure thereof. However, general means having conventionally been employed for integrally forming a box-geometry structure, such as the following, can be adopted. A projection is formed at a predetermined portion on the 11d section 11a; a concavity is formed in a predetermined portion of the box section 11b opposing the projection; and the pair consisting of the projection and the concavity are fitted to each other, thereby allowing attachment or detachment with a single motion.

Inside the shielding case 11 configured as above, the circuit board 12 is housed and arranged in a state in which the bottom face and the top face thereof are shielded. In this case, an inner bottom face of the box section 11b of the shielding case 11 and the circuit board 12 are arranged substantially parallel with each other; and in this state, the 11d section 11a is attached so as to cover an opening side (an upper face side of the circuit board 12) of the box section 11b. Here, the flat face of the 11d section 11a is arranged substantially parallel with the mounting face of the circuit board 12.

In addition, as described above, the hole 11c is formed in a predetermined portion of the 11d section 11a of the shielding case 11. The hole 11c is formed at a portion opposing an upper face of the heat-generating member 13 to be mounted on the circuit board 12 which is to be housed and arranged inside the shielding case 11 in a state in which the shielding case 11 has been assembled.

As described above, the thermal-conduction sheet 14, which is a thermal-conduction member, is affixed on the upper face of the heat-generating member 13. A conventionally-employed sheet is adopted as the thermal-conduction sheet 14, wherein a flexible, highly-thermal-conductive member; e.g., a silicone material; a non-silicone material such as an acrylic rubber; aluminum; or a graphite material, is sandwiched.

As illustrated in FIGS. 3 and 4, the heat-radiating member 15 is formed by means of, e.g., folding an elastic, thin-plate-like metal material, or the like. The overall geometry thereof is a substantially polygonal sleeve, and a gathered bellows section 15a is formed on side faces. An opening 15b is formed on one end of the heat-radiating member 15, thereby forming a storage section 15c in which a predetermined coolant 17, such as a liquid (fluid) medium, e.g., water; a filamentary member, such as steel wool; gel medium; and the like, can be housed. A lid-receiving section 15d is formed on the circumference of the opening. Onto the lid-receiving section 15d, a 11d member 16 is to be integrally attached. Thus, when the 11d member 16 is attached, contents of the storage section 15c are sealed therein.

An outer side of the bottom face of the heat-radiating member 15 is formed into a flat face. As described above, the flat face comes into contact with the upper face of the heat-generating member 13 with the thermal-conduction sheet 14 therebetween, thereby pinching the thermal-conduction sheet 14. Accordingly, the outer flat face of the bottom face of the heat-radiating member 15 is formed parallel with respect to the upper face of the heat-generating member 13.

The bellows section 15a of the heat-radiating member 15 has elasticity and is formed retractably. A snap-in section 15e having the geometry of an outward radial projection is formed at a portion of the bellows section 15a close to the opening around the periphery. In addition, a positioning section 15f having the geometry of an inward radial projection is formed at a portion which is adjacent to the snap-in section 15e and which is located higher than the same.

Meanwhile, as illustrated in FIG. 4, when a width between peaks (outer side) of the snap-in section 15e is taken as L1; a maximum width of the bellows section 15a is taken as L2; a width between peaks (inner side) of the positioning section 15f is taken as L3; and a maximum width of the opening 15b is taken as L4, dimensional relations among the respective dimensions are set as follows.
L3<L2<L4<L1

The reason for employing such dimensional relations is as follows. Namely, the maximum width L2 of the bellows section 15a is set to be smaller than the maximum width L4 of the opening 15b (L2<L4). At the time of attaching the heat-radiating member 15 to the shielding case 11, this enables the bellows section 15a of the heat-radiating member 15 to be placed, without impediment, inside the shielding case 11 through the hole 11c, from the upper face side of the 11d section 11a of the shielding case 11.

The width L1 between the peaks (outer side) of the snap-in section 15e is set to be smaller than the maximum width L4 of the opening 15b (L4<L1). The reason for this is that an inner circumference of the opening 15b to be fit in a trough (outer side) of the positioning section 15f, thereby attaining positioning of the heat-radiating member 15.

More specifically, at the time of attachment of the heat-radiating member 15 to the shielding case 11, as described above, the bellows section 15a of the heat-radiating member 15 is inserted through the hole 11c from the upper face side of the 11d section 11a of the shielding case 11. Thus, after the bellows section 15a has passed through the hole 11c without impediment, a slope 15ea on one side (lower side) of the snap-in section 15e of the heat-radiating member 15 comes into contact with the inner circumference of the hole 11c of the 11d section 11a of the shielding case 11. The heat-radiating member 15 is temporarily engaged here.

In this state, a force in a direction indicated by reference symbol F in FIG. 4 is applied to the heat-radiating member 15. Subsequently, since, as described above, the heat-radiating member 15 is formed from an elastic member, a portion of the snap-in section 15e in the vicinity of the opening 15b is pressed by the inner circumference of the hole 11c, thereby being deformed in the direction indicated by the reference symbol F2 in FIG. 4. At this time, the slope 15ea of the snap-in section 15e slides along the inner circumference of the hole 11c while being in contact therewith. Thus, the heat-radiating member 15 per se moves in the direction indicated by the arrow F.

When the inner circumference of the hole 11c surmounts the peak of the snap-in section 15e, elastic resilience of the heat-radiating member 15 causes the inner circumference of the hole 11c to slide along a slope 15eb on the other side of the snap-in section 15e. Eventually, the inner circumference of the hole 11c is entrapped in the trough of the positioning section 15f. As a result, the heat-radiating member 15 is positioned as indicated in FIG. 4.

Meanwhile, inside the storage section 15c of the heat-radiating member 15, the predetermined coolant 17 is sealed as described above. In this case, the coolant 17 is not filled completely inside the storage section 15c, which is a sealed space formed by the 11d member 16; and, as indicated by reference symbol A in FIG. 4, the coolant 17 is filled in a state in which a given allowance of space is ensured. Thus, by virtue of ensuring a given allowance of space in the storage section 15c, the coolant 17 can freely move inside the storage section 15c. Accordingly, the coolant 17 moves inside the storage section 15c, to thus be agitated, thereby contributing to enhancement of heat-radiating effect.

As described above, according to the embodiment, the electronic apparatus 10 is configured such that the hole 11c is formed in the 11d section 11a of the shielding case 11; the heat-radiating member 15 formed from an elastic, thin-plate-like metal material is attached to the hole 11c; and one flat face of the heat-radiating member 15 and a flat face of the heat-generating member 13 are brought into contact with the thermal-conduction sheet 14 therebetween. The heat-radiating member 15 includes the gathered bellows section 15a on the side faces, and the predetermined coolant 17 is filled inside. By virtue of this configuration, heat released from the heat-generating member 13 is conducted to the shielding case 11 by way of the thermal-conduction sheet 14 and the heat-radiating member 15 without fail. Accordingly, the electronic apparatus 10 of the embodiment can radiate heat toward the outside of the shielding case 11 efficiently and without fail. Therefore, heat is not built up inside the electronic apparatus 10, and radiation of heat of the heat-radiating member 13 can be attained without fail. As a result, an increase of the temperature of the heat-generating member 13 and the electronic apparatus per se can be suppressed, thereby ensuring stability of the apparatus in all cases.

Meanwhile, in the previously-described embodiment, the overall shape of the heat-radiating member 15 is a substantially polygonal sleeve; however, no limitation is imposed thereto. For instance, the same may be formed into a substantially cylinder geometry in overall shape with a bellows section on a side face thereof. Even when the heat-radiating member is formed into another geometry in overall shape as described above, there can be yielded the same effects as those yielded in the above-described embodiment.

What is claimed is:

1. An electronic apparatus comprising:
a circuit board on which a heat-generating member is mounted;
a shield case; and
a heat-radiating member attached to the shield case for radiating heat released from the heat-generating member,
wherein the heat-radiating member comprises side faces formed with bellows-like gathers.

2. The electronic apparatus according to claim 1, wherein a coolant is stored in the heat-radiating member.

3. The electronic apparatus according to claim 1, wherein the heat-radiating member is formed so as to have elasticity in a direction of pressing one flat face of the heat-generating member; and
a heat-conduction member is pinched between one flat face of the heat-radiating member and the flat face of the heat-generating member.

4. The electronic apparatus according to claim 1, wherein
the coolant is made from liquid medium; and
the heat-radiating member is sealed while ensuring a predetermined allowance of space so that the coolant can move inside the heat-radiating member.

5. The electronic apparatus according to claim 1, wherein
the coolant is made from gel medium; and
the heat-radiating member is sealed while ensuring a predetermined allowance of space so that the coolant can move inside the heat-radiating member.

6. The electronic apparatus according to claim 1, wherein
the coolant is made from solid medium; and
the heat-radiating member is sealed while ensuring a predetermined allowance of space so that the coolant can move inside the heat-radiating member.

7. The electronic apparatus according to claim 1, wherein the side faces extends toward the inside of the shield case.

8. The electronic apparatus according to claim 7, wherein the side faces form a sleeve.

9. The electronic apparatus according to claim 8, wherein the sleeve formed by the side faces has a polygonal-sleeve shape.

10. A television receiver comprising:
an electronic apparatus including a circuit board on which a heat-generating member is mounted, a shield case and a heat-radiating member attached to the shield case for radiating heat released from the heat-generating member; and
an image-display device for displaying an image,
wherein the heat-radiating member comprises side faces formed with bellows-like gathers;
the heat-radiating member is formed so as to have elasticity in a direction of pressing one flat face of the heat-generating member; and
a heat-conduction member is pinched between one flat face of the heat-radiating member and the flat face of the heat-generating member.
